(19) United States
(12) Patent Application Publication
(10) Pub. No.: US 2007/0247937 A1
(43) Pub. Date: Oct. 25, 2007

(54) INFORMATION PROCESSING SYSTEM FOR CALCULATING THE NUMBER OF REDUNDANT LINES OPTIMAL FOR MEMORY DEVICE

(75) Inventors: Ichiro Moriyama, Tokyo (JP); Seiji Ishikawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/736,435

(22) Filed: Apr. 17, 2007

(30) Foreign Application Priority Data
Apr. 19, 2006 (JP) 2006-115234

(51) Int. Cl. G11C 29/00

(52) U.S. Cl. 365/200

(57) ABSTRACT

An information processing system of the invention has a database in which test results for a plurality of memory devices mounted on a wafer are stored and a computer for analyzing the test results. The computer includes a data retrieval section for retrieving a test result from the database; and a required redundant line quantity calculation section for determining the total number of redundant lines which is required for recovering failed bits of the memory device based on the test results, deciding how the required total number of redundant lines should be assigned in each of the row and column directions, and calculating the total number of redundant lines required for recovery and the number of redundant lines assigned in each of the row and columns directions on the memory device, and the computer displays a result of calculation by the required redundant line quantity calculation section.

This application is based upon and claims the benefit of priority from Japanese Patent Application No. 2006-115234 filed on Apr. 19, 2006, the content of which is incorporated by reference.

### BACKGROUND OF THE INVENTION

1. Field of the Invention:

The present invention relates to a required redundant line quantity calculation system and a defect analysis method for efficiently analyzing defects of semiconductor memory products and particularly for calculating the number of redundant lines which is required for recovery of defects.

2. Description of the Related Art:

As the width of processed lines of semiconductor products has become thinner and thinner, manufacturing then has been increasingly difficult as well. It is thus important to classify the types of defects which occur in manufacturing, take some measures appropriate for each type of defect and improve the manufacturing yield. For a memory product, the position of a memory element (or a memory cell) that does not function normally (hereinafter referred to as a “failed bit”) is indicated on the display device of a computer or the like being expressed as arrangement of memory elements of a device. Then, by making classification based on the displayed distribution of failed bits itself and/or the characteristics of the distribution, measures can be planned efficiently. This method is called “failed bit analysis”.

The storage area of a memory product is typically divided into a number of blocks, in each of which memory elements are two-dimensionally and regularly arranged in a matrix. The direction of one of two axes of the two-dimensional storage area is called row direction and that of the other axis is called column direction. The position of a failed bit is uniquely determined by a coordinate in the row direction and a coordinate in the column direction.

An actual memory product includes a separate storage area for recovering failed bits. This storage area is called a redundant area. By recovering failed bits in the redundant area, the product can secure a storage capacity which is guaranteed as a product specification even if some failed bits exist.

Thus, for addressing defects as well, it is economically more reasonable to devise a measure which reduces the total number of failed bits to a level at which their recovery is possible rather than a perfect measure which eliminates every failed bit that exists on a chip.

In view of such situations as outlined above, techniques for planning effective measures for securing yield in failed bit analysis, taking into consideration of recoverability of individual chips, are disclosed in Japanese Patent Laid-Opens No. 2000-311842 (hereinafter “Patent Document 1”) and No. 2000-298998 (hereinafter “Patent Document 2”).

The technique disclosed in Patent Document 1 predicts how failed bits would be distributed after some measure is taken for distribution of failed bits on a wafer, determines yield resulting from the measure for distribution of failed bits before and after implementation of the measure, and considers the difference to be the effect of the measure. When it determines yield, the technique takes into consideration recoverability of failed bits by means of a redundant area.

The technique disclosed in Patent Document 2 determines whether individual failed bits can be recovered in consideration of their distribution on a chip for distribution of failed bits on a wafer, and extracts ones which cannot be recovered as critical defects so as to improve yield efficiently.

The techniques to consider recoverability in Patent Document 1 and the techniques to attempt extraction of critical defects in Patent Document 2 both use a certain number of redundant lines in a row or column direction which is prescribed when a product is manufactured.

However, when a new product is developed along with launch of a new manufacturing process therefor, it is sometimes necessary to understand how many redundant lines should be prepared in connection with a problem specific to the manufacturing process. This need is not satisfied by the two techniques described in Patent Documents 1 and 2.

### SUMMARY OF THE INVENTION

It is an object of the invention to provide an information processing system and a defect analysis method which can facilitate proper design of redundant lines for a memory device.

The information processing system of the invention includes a required redundant line quantity calculation section which determines the total number of redundant lines required for recovering failed bits of a memory device, decides how the required total number of redundant lines should be assigned in each of the row and column directions, and calculates the total number of redundant lines required for recovery and the number of redundant lines assigned in each of the row and column directions on the memory device.

When it decides the direction of a redundant line, if there are two or more failed bits in the same redundant line, the required redundant line quantity calculation section can decide the direction of a redundant line which passes through those failed bits. However, when the same line contains no other defects (hereinafter referred to as a “single-bit defect”), the required redundant line quantity calculation section may be unable to decide the direction of a redundant line. Accordingly, when a redundant line is to be assigned, it is preferable to count the number of failed bits for which the direction of a redundant line cannot be decided. It is also preferable to separately count the number of failed bits for which the direction of a redundant line cannot be decided when the number of redundant lines to be used is calculated.

Further, the invention provides the required redundant line quantity calculation section in a computer system which has a tester for testing the wafer on which semiconductor devices are mounted and a computer and a database which are connected to the tester via a network. It is accordingly possible to understand the required number of redundant lines when a new process is launched and to compare the number of redundant lines which are reasonably prepared in products of the new process with the number of redundant lines of any other process.

According to the invention, because the required number of redundant lines is evaluated based on the distribution of failed bits which occur on an actually manufactured wafer, the proper design of redundant lines is facilitated, which can improve the yield of manufactured memory products.

The above and other objects, features and advantages of the present invention will become apparent from the following description with reference to the accompanying drawings which illustrate examples of the present invention.

### BRIEF DESCRIPTION OF THE DRAWINGS

FIG. 1 shows a block diagram showing an exemplary configuration of a required redundant line quantity calculation system of an embodiment;

FIG. 2 illustrates the configuration of a target device for the required redundant line quantity calculation system of the embodiment;

FIG. 3A illustrates an example of a maximum matching in the required redundant line quantity calculation system of the embodiment;

FIG. 3B illustrates an example which is not a maximum matching in the required redundant line quantity calculation system of the embodiment;

FIG. 4 shows a flow diagram illustrating an algorithm for determining the required number of redundant lines in the required redundant line quantity calculation system of the embodiment;

FIG. 5 shows a flow diagram illustrating processing for determining the maximum matching included in the flow diagram shown in FIG. 4;

FIG. 6 illustrates a bipartite graph for the required redundant line quantity calculation system of the embodiment;

FIG. 7A illustrates an example of failed bit distribution in the required redundant line quantity calculation system of the embodiment;

FIG. 7B shows a bipartite representation of FIG. 7A;

FIG. 8 shows a flow diagram illustrating processing for deciding the direction of a redundant line included in the flow diagram shown in FIG. 4 that is performed in the required redundant line quantity calculation system of the embodiment;

FIG. 9 illustrates the concept of displaying of a failed bit map for use in a wafer in the required redundant line quantity calculation system of the embodiment;

FIG. 10 shows an exemplary display of the result of analyzing the required number of redundant lines at chip level in the required redundant line quantity calculation system of the embodiment;

FIG. 11A illustrates an example of a failed bit map for use in a wafer for the required redundant line quantity calculation system of the embodiment; and

FIG. 11B shows an exemplary display of the result of required quantity analysis at wafer level for the failed bit map for use in a wafer shown in FIG. 11A.

### DETAILED DESCRIPTION OF THE PREFERRED EMBODIMENT

Hereinafter, similar components are given the same reference numerals in all figures illustrating an embodiment of the invention and their repeated description is omitted.

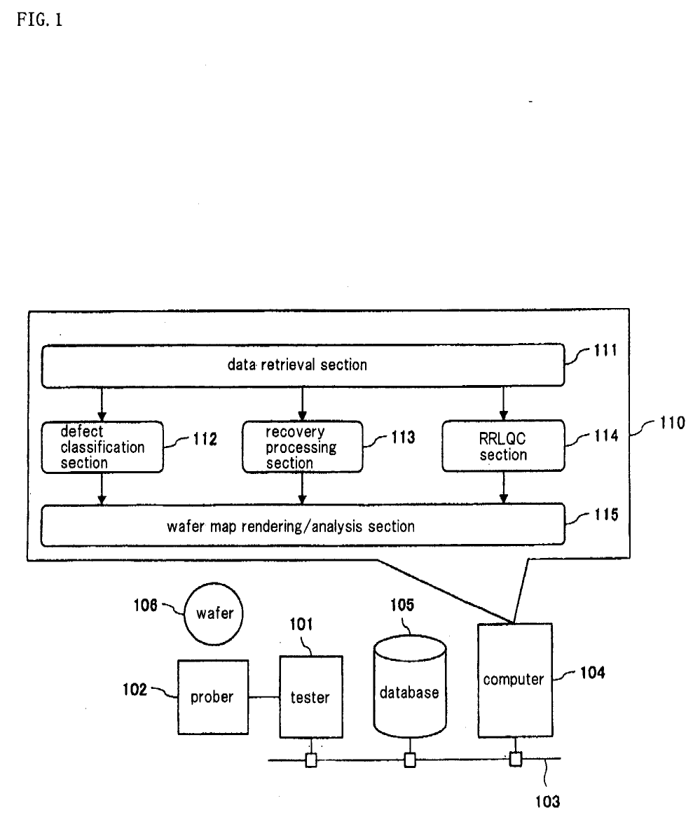

FIG. 1 shows a configuration of a required redundant line quantity calculation system. With reference to FIG. 1, an exemplary configuration of the required redundant line quantity calculation system of an embodiment will be described.

The required redundant line quantity calculation system of the embodiment includes tester 101 and prober 102 for testing a memory device which will be a semiconductor memory product, database 105 for storing results of tests with tester 101, and computer 104 for calculating a required quantity of redundant lines from a test result. Tester 101, computer 104, and database 105 are connected to each other via network 103. The required redundant line quantity calculation system is equivalent to an information processing system which has database 105 and computer 104.

When wafer 106 for testing is attached, prober 102 detects the row and column directions of a plurality of chips mounted on wafer 106 and brings a measuring needle into contact with the electrode pad of the first predetermined chip. When tester 101 finishes testing the chip, the measuring needle is removed once from wafer 106 and wafer 106 is moved for a predetermined distance. Then, the measuring needle is brought into contact with an electrode pad of the next chip for testing in a predetermined sequence and tester 101 executes testing. Subsequently, movement of wafer 106 is repeated on a per-chip basis until all chips for testing on wafer 106 are measured by tester 101.

Tester 101 prestores therein a program for determining failure/non-failure of each memory element of chips on wafer 106. Upon receiving a signal indicating readiness to start testing of wafer 106 from prober 102, tester 101 measures individual chips on wafer 106 to identify failed bits for each memory element, and generates data which represents the occurrence of failed bits. The data representing the result of measurement is registered in database 105 by way of network 103 and computer 104.

Computer 104 includes data retrieval section 111 for retrieving data desired by a user in accordance with the user's operations, defect classification section 112 for classifying defects that have occurred, recovery processing section 113 for recovering defective bits by utilizing the resource of redundant lines provided in a device, required redundant line quantity calculation section (hereinafter represented to as a “RRLQC section”) 114 for calculating the required number of redundant lines, and wafer map rendering/analysis section 115 for rendering a calculation result as a map on a wafer and analyzing the same.

Computer 104 includes a central processing unit (CPU) not shown and memory (not shown) for storing programs. Through execution of a program by the CPU, the sections illustrated in box 110 of FIG. 1 are virtually implemented in computer 104. The memory (not shown) of computer 104 serves as temporarily storage for the result of testing wafer 106.

The user operates computer 104 to retrieve a test result from database 105 when needed and has computer 104 analyze it and display the result of the analysis on a display device (not shown), such as a CRT.

This embodiment mainly relates to functions of RRLQC section 114 and wafer map rendering/analysis section 115. As will be described in more detail below, RRLQC section 114 determines the total number of redundant lines required for recovering failed bits of a chip, decides how the required total number of redundant lines should be assigned in row and column directions, and calculates the total number of redundant lined required for recovery and the number of redundant lines assigned to each of the row and column directions on the single chip.

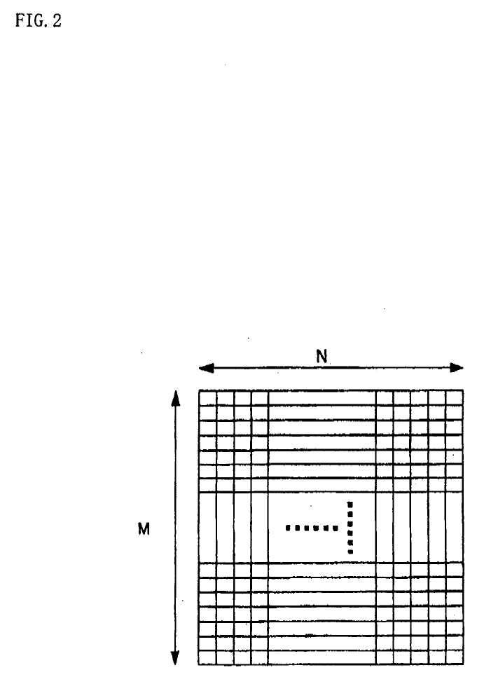

Referring to FIGS. 2 to 8, an algorithm will be described which is executed by RRLQC section 114 for determining the number of redundant lines required for recovery.

First, with reference to FIG. 2, an exemplary configuration of a target device will be described. For illustration, this embodiment uses a device which has a single two-dimensional storage area consisting of M vertical and N horizontal memory cells. For an actual device, a storage area of the actual device is divided into a plurality of such areas and/or two areas from among a plurality of such areas are replaced. Such a device can be treated by repeating the algorithm described in this embodiment as many times as the number of areas, or by adding an algorithm for excluding overlapping counts that result from simultaneous substitution as appropriate.

Herein, the problem of assigning a redundant line to a failed bit of a device is replaced with the problem of drawing straight lines which cover “1”s among dots of “0” and “1” that exist in a M×N two-dimensional matrix. A non-defective bit is represented by “0” and a failed bit is represented by “1”. It is known here that the minimum number (i.e., the number of minimum covers) of straight lines that cover all “1”s is equal to the maximum number (i.e., the number of maximum matchings) of “1”s which are on different lines (see Ochiai Mitsuyuki, Graph Theory Primer, published by Nihon-hyoron-sha, p. 63, Theorem 4.8). Theorem 4.8 describes that |M|=|K| holds for the number (M) of maximum matchings and the number (K) of minimum covers of a bipartite graph.

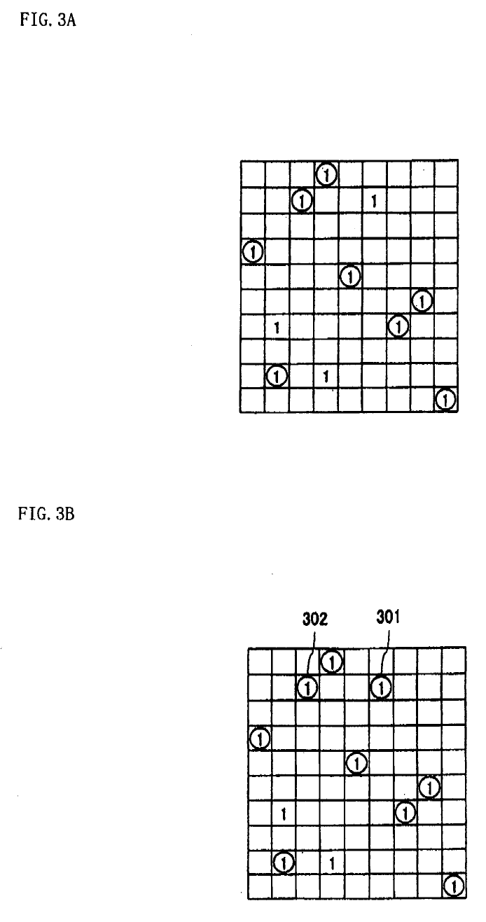

Referring to FIGS. 3A and 3B, an example of a maximum matching and an example which is not a maximum matching will be described. FIG. 3A shows an example of a maximum matching and FIG. 3B shows an example which is not a maximum matching.

In both FIGS. 3A and 3B, “0”s representing non-defective bits are not shown and only “1”s representing failed bits are shown. A “1” with a circle represents a point which gives a maximum matching. All “1”s with a circle are in different rows and columns. Such positioning of maximum “1”s with a circle represents the combination of points that give a maximum matching.

The same distribution of failed bits and distribution of maximum matching as in FIG. 3A are shown in FIG. 3B and a failed bit illustrated at 301 is newly given a circle. Then, failed bit 301 is on the same row line as failed bit 302. In FIG. 3B, if any “1” other than failed bit 301 is given a circle, its row or column line will always contain another circle. Thus, it can be proved that FIG. 3A represents a maximum matching.

In this way, by assuming “1” to be a failed bit and “0” to be a non-defective bit, a problem of determining the minimum number (i.e., the number of minimum covers) of redundant lines required for recovery of failed bits can be reduced to determining the number (i.e., the number of maximum matchings) of failed bits which exist on a different straight line.

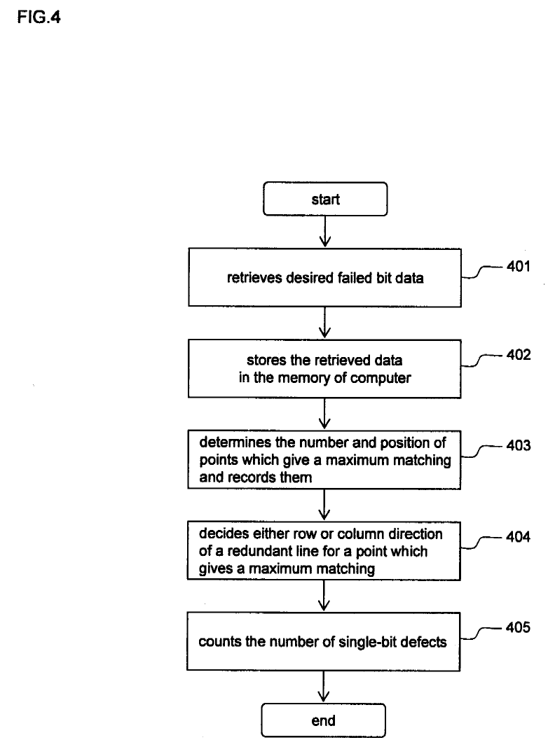

Now, with reference to the flow diagram shown in FIG. 4 and the description on maximum matching provided above, an exemplary flow of an algorithm for determining the required number of redundant lines will be described.

At step 401, RRLQC section 114 retrieves desired failed bit data from database 105. It is assumed here that failed bit data is described by “1”s and non-defective bit data is described by “0”s.

At step 402, RRLQC section 114 stores the retrieved data in the memory of computer 104 according to the vertical and horizontal size of the device. In the memory, information on whether a bit is a failed bit or a non-defective bit is recorded in correspondence with the position of each memory element of the device.

At step 403, RRLQC section 114 determines the number and position of points which give a maximum matching and records information on the number and position of these points.

At step 404, RRLQC section 114 decides either row or column direction of a redundant line for a point which gives a maximum matching.

At step 405, RRLQC section 114 counts the number of failed bits that have no other failed bits in both the row and column directions (which is called a “single-bit defect”).

Step 404 can be omitted when the only purpose is to determine the minimum number of redundant lines required for recovery. However, since it is also effective to take into consideration the arrangement of redundant lines, it is worth providing step 404.

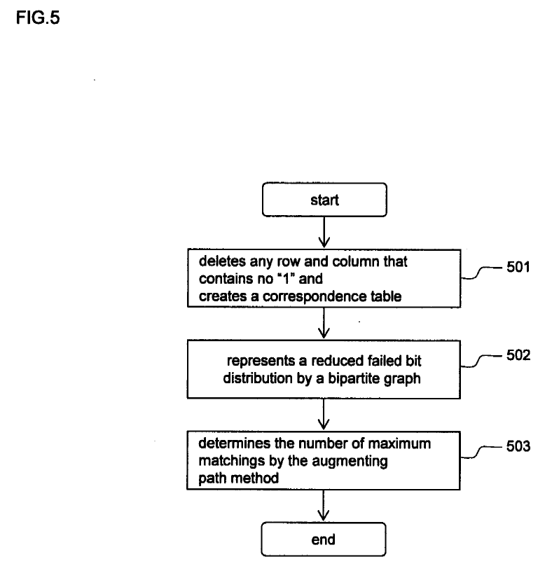

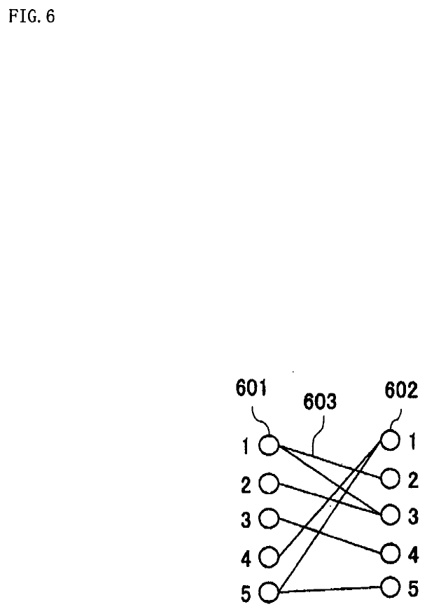

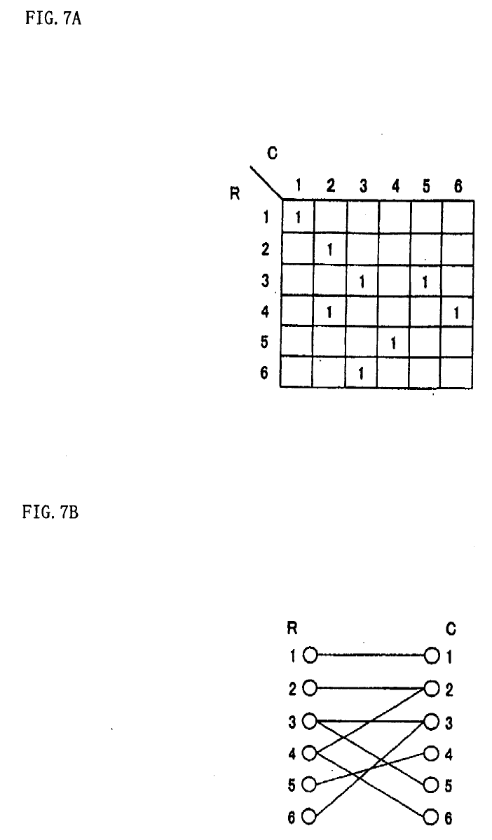

Using the flow diagram of FIG. 5 and referring to FIGS. 6, 7A and 7B, processing (i.e., determination of the number of maximum matchings) done at step 403 of FIG. 4 will be described in detail.

The procedure for determining the number of maximum matchings is also generally known as the augmenting path method (see Alfred V. Aho, John E. Hopcroft, and Jeffrey D. Ullman, translated by Ohno Yoshio, Data Structures and Algorithms, published by Baifukan, pp. 215-216).

Using the augmenting path method, an algorithm for determining the minimum number of redundant lines required for recovery will be described.

At step 501, RRLQC section 114 deletes any row and column that contains no “1” from a failed bit map of a two-dimensional matrix in which failed bits are distributed, and creates a matrix which is a reduction of the original failed bit map. It also creates a correspondence table which shows the correspondence of row and column positions before and after the deletion.

At step 502, RRLQC section 114 represents the reduced matrix as a so-called bipartite graph (see FIG. 6). As illustrated in FIG. 6, left vertices 601 are assumed to be row numbers and right vertices 602 to be column numbers, and a position at which “1” exists is represented by connecting a row-side point and a column-side point (reference numeral 603 in FIG. 6). FIG. 7A shows a simplified matrix representation of reduced failed bit distribution and FIG. 7B shows a bipartite representation of the same.

At step 503, RRLQC section 114 applies the augmenting path method to determine the position of a failed bit which gives the number of maximum matchings and stores the position.

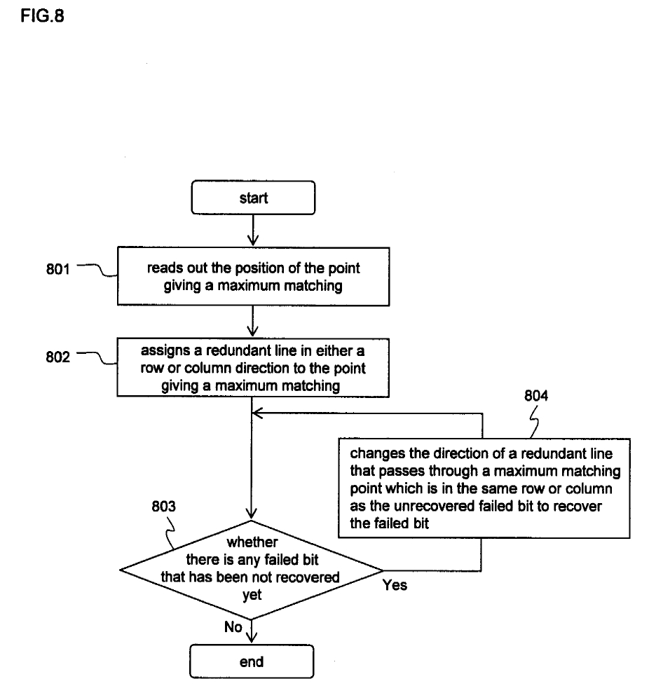

Now, with respect to the flow diagram shown in FIG. 8, processing (i.e., decision of a redundant line direction) done at step 404 of FIG. 4 will be described in detail.

At step 801, RRLQC section 114 reads out the position of the failed bit (or a point) giving a maximum matching which was stored at step 403 in FIG. 4.

At step 802, RRLQC section 114 assigns a redundant line in either a row or column direction to the failed bit (or point) giving a maximum matching. At this point, it is preferable to assign the redundant line in a direction which has less vertices in a bipartite graph representation. For a case in which there are the same number of vertices in row and column directions, the direction of higher priority is predetermined and a redundant line is assigned accordingly.

At step 803, RRLQC section 114 determines whether there is any failed bit that has been not recovered yet. If there is no failed bit that has been not recovered yet, processing is terminated. However, if there is any failed bit not yet recovered, the process proceeds to step 804.

At step 804, RRLQC section 114 changes the direction of a redundant line that passes through a maximum matching point which is in the same row or column as the unrecovered failed bit to thereby recover the failed bit.

If changing the direction of redundant line L1, that is already assigned, were to newly cause the occurrence of an unrecovered failed bit, L1 will not be changed and the direction of redundant line L2, which passes through another failed bit which gives a maximum matching, will be changed. If L2 does not exist or if another unrecovered failed bit were to be newly caused as a result of changing L2, then the direction of L1 will be changed.

These operations are repeated until there is no failed bit to which no redundant line is assigned.

In this manner, it is possible to determine the minimum number and position of redundant lines which can recover failed bits for a given distribution of failed bits.

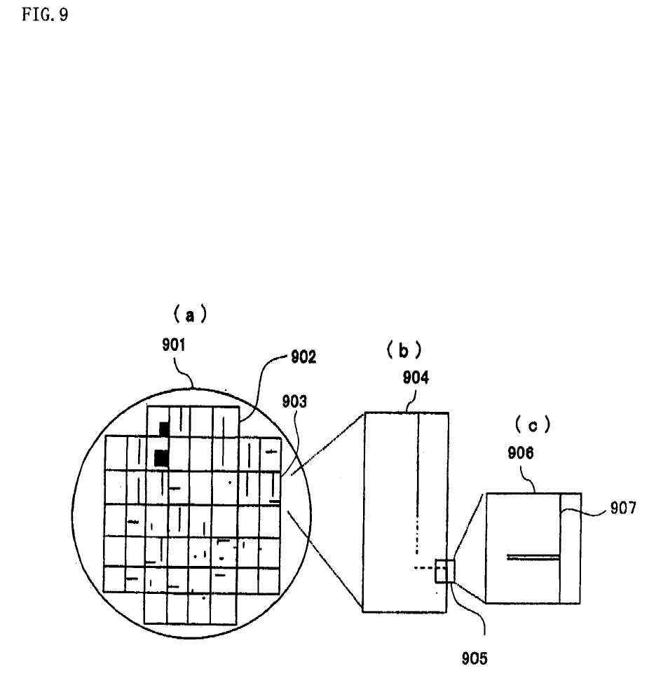

Now, with respect to FIGS. 9 to 11 B, description will be given of an overview of display and analysis functions for a failed bit map for use in a wafer which are executed by wafer map rendering/analysis section 115.

As a failed bit map for use in a wafer is disclosed in Patent Documents 1 and 2 mentioned above, it is described only briefly here.

FIG. 9(a) to FIG. 9(c) shows the concept for displaying a failed bit map for use in a wafer.

As illustrated in FIG. 9(a), wafer map rendering/analysis section 115 displays scribing lines 902 on wafer 901, which has an approximately circular shape, for segmenting it into chips and for clarifying the arrangement of the chips. Failed bits are indicated by a dot, line segment, and/or a rectangle of black or red at a position which approximately corresponds to where the failed bits have occurred. When failed bits are indicated by a line segment or a rectangle, it means that failed bits are distributed in the form of a segment or a rectangle at that position.

When displayed, approximate distribution of failed bits is displayed to the resolution precision of the display device (not shown) of computer 104. When the user indicates interest in chip 903 in the wafer map display, wafer map rendering/analysis section 115 enlarges that chip as illustrated in FIG. 9(b). In FIG. 9(b), chip 903 after enlargement is illustrated at reference numeral 904. Wafer map rendering/analysis section 115 then displays the distribution of failed bits within chip 904.

When the user indicates interest in area 905 in the displayed chip, wafer map rendering/analysis section 115 enlarges that area as illustrated in FIG. 9(c). In FIG. 9(c), area 905 after enlargement is illustrated at reference numeral 906. If area 906 contains edge 907 of the chip, edge 907 is desirably displayed together with area 906. It is preferable that this enlargement can be executed in several levels.

Based on such a display function, analysis (i.e., required quantity analysis function) of the number of redundant lines required for recovering the given distribution of failed bits is performed.

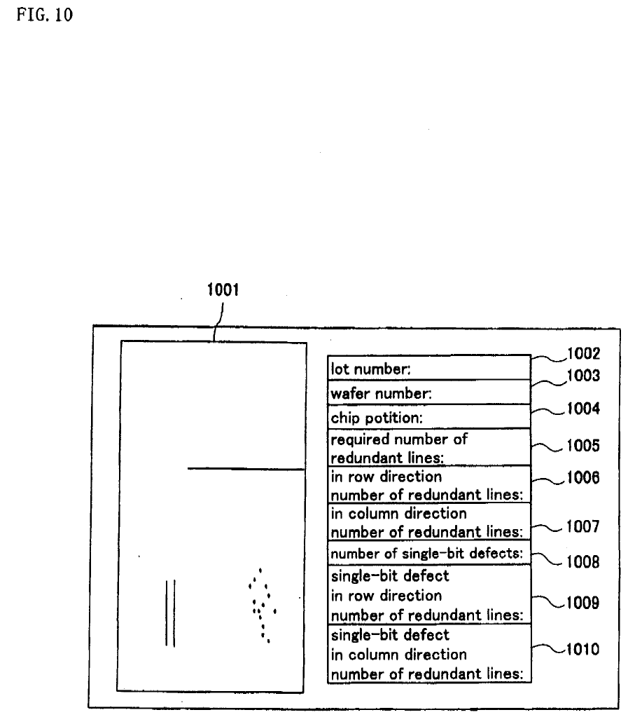

An analysis method for the required quantity analysis function and a method for displaying the result will be described below. FIG. 10 illustrates an exemplary display of a result of required quantity analysis at the chip level.

As illustrated in FIG. 10, wafer map rendering/analysis section 115 displays lot number 1002, wafer number 1003, chip position 1004, the required number 1005 of redundant lines, the number 1006 of redundant lines assigned in a row direction, and the number 1007 of redundant lines assigned in a column direction for a chip in question, at the side of failed bit distribution display 1001 for the chip. It also displays the number 1008 of single-bit defects, the number 1009 of row redundant lines and the number 1010 of column redundant lines which are assigned to the single-bit defects. Since either a row or column redundant line may be assigned to a single-bit defect, how to assign redundant lines is as arbitrary as the number of single-bit defects.

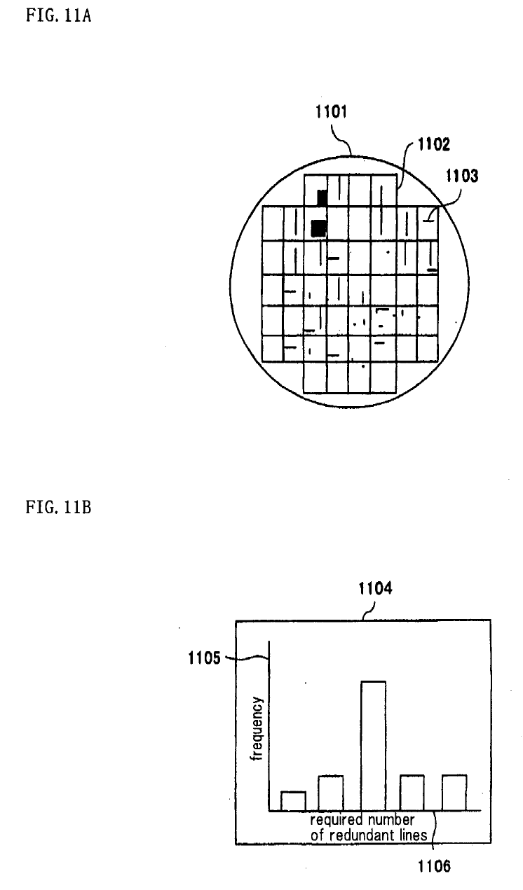

Then, as illustrated in FIG. 11A, wafer map rendering/analysis section 115 displays wafer map 1101 which shows chip outlines 1102 on the wafer and distribution of failed bits 1103. An exemplary display of the result of required quantity analysis at wafer level for the failed bit map for use in the wafer shown in FIG. 11A is illustrated in FIG. 11B.

As illustrated in FIG. 11B, wafer map rendering/analysis section 115 also displays the result of statistical analysis on numerical values displayed from the required number 1005 of redundant lines to the number 1010 of column redundant lines of FIG. 10, e.g., the required number of redundant lines and the number of single-bit defects, at the side of display of wafer map 1101. By way of example, histogram 1104 for the required number of redundant lines is shown here. The vertical axis represents frequency 1105 and the horizontal axis represents the required number 1106 of redundant lines.

It is assumed that target data for analysis is test results for individual chips of a wafer which are shown in a wafer map. Since the range of the horizontal axis can be extremely large for a recent memory device having a large storage area, it is preferable to provide a function for flexibly changing a segment for which frequency is calculated and/or a function for truncating display of the horizontal axis when a graph is drawn.

As has been thus described, this embodiment can evaluate the required number of redundant lines based on distribution of failed bits occurring on a wafer actually manufactured. Specifically, by determining the minimum redundant lines that can recover failed bits based on the distribution of the failed bits for each chip, it is possible to give an estimate of the number of redundant lines that should be set in either the row or column direction when redundant lines are designed. This facilitates proper design of redundant lines, which can improve the yield of manufactured memory products.

Also, by using a result from defect classification section 112 (see FIG. 1) which classifies defects, to extract and delete only certain defects and then by calculating the required number of redundant lines, it is possible to understand the number of redundant lines that is required after addressing the cause of the extracted defects.

Also, by using a result given by recovery processing section 113 (see FIG. 1) which assigns a predetermined number of redundant lines to failed bits and determines whether they can be recovered or not, it is possible to extract chips that could not be recovered with the predetermined number of redundant lines and to calculate the number of redundant lines required for those chips, thereby improving efficiency of processing.

As has been described above, the present invention differs from the methods of Patent Documents 1 and 2 which determine whether failed bits of a chip can be recovered or whether these are critical defects by use of a given number of redundant lines.

The present invention relates to a technique for efficiently analyzing defects of semiconductor memory products and is particularly effective when applied to a technique for calculating the number of redundant lines required for recovery of defects.

The defect analysis method of the invention may be applied to a program for causing a computer to execute the method, and the program may be recorded on a computer-readable recording medium.

While a preferred embodiment of the present invention has been described using specific terms, such description is for illustrative purposes only, and it is to be understood that changes and variations may be made without departing from the spirit or scope of the following claims.

What is claimed is:

1. An information processing system having a database in which test results for a plurality of memory devices mounted on a wafer are stored and a computer for analyzing said test results, wherein
said computer comprises:
a data retrieval section for retrieving said test results from said database; and
a required redundant line quantity calculation section for determining a total number of redundant lines which is required for recovering failed bits of a memory device based on said test results, deciding how the required total number of redundant lines should be assigned in each of a row and column directions, and calculating the total number of redundant lines required for recovery and the number of redundant lines assigned in each of the row and column directions on said memory device, and
said computer displays a result of calculation by said required redundant line quantity calculation section.

2. The information processing system according to claim 1, wherein
said computer further comprises:
a defect classification section for classifying defective memory elements from said test results; and
a recovery processing section for assigning a predetermined number of redundant lines to failed bits and determining whether the failed bits can be recovered or not.

3. The information processing system according to claim 2, wherein said required redundant line quantity calculation section uses a result from said defect classification section to delete only certain defective memory elements and calculate the required number of redundant lines.

4. The information processing system according to claim 2, wherein said required redundant line quantity calculation section uses a result from said recovery processing section to calculate the required number of redundant lines for a memory device which cannot be recovered with a predetermined number of redundant lines.

5. The information processing system according to claim 1, further comprising
a tester for testing the wafer, wherein
said database and said computer are connected to said tester via a network.

6. A defect analysis method using an information processing system which has a database in which test results for a plurality of memory devices mounted on a wafer are stored and a computer for analyzing said test results, the method performing required redundant line quantity calculation for:
determining a total number of redundant lines which is required for recovering failed bits of a memory device based on the test results;
deciding how the required total number of redundant lines should be assigned in each of a row and column directions; and
executing a required redundant line quantity calculation to calculate the total number of redundant lines required for recovery and the number of redundant lines assigned in each of the row and column directions on said memory device.

7. The defect analysis method according to claim 6, wherein said required redundant line quantity calculation uses a result of defect classification processing which classifies defective memory elements from said test results to delete only certain defective memory elements and calculate the required number of redundant lines.

8. The defect analysis method according to claim 6, wherein said required redundant line quantity calculation calculates the required number of redundant lines for a memory device which cannot be recovered with a predetermined number of redundant lines using a result of recovery processing which assigns a predetermined number of redundant lines to failed bits and determines whether the failed bits can be recovered or not.

9. A recording medium having recorded thereon a program readable by a computer for analyzing test results for a plurality of memory devices mounted on a wafer, the program causing the computer to execute a required redundant line quantity calculation for:
determining a total number of redundant lines which is required for recovering failed bits of a memory device based on said test results;
deciding how the required total number of redundant lines should be assigned in each of a row and column directions; and
calculating the total number of redundant lines required for recovery and the number of redundant lines assigned in each of the row and column directions on said memory device.
